(19) United States
(12) Patent Application Publication
(10) Pub. No.: US 2020/0111704 A1
(43) Pub. Date: Apr. 9, 2020

(54) METHODS OF FORMING STRESS LINERS USING ATOMIC LAYER DEPOSITION TO FORM GAPFILL SEAMS

(71) Applicant: GLOBALFOUNDRIES Inc., Grand Cayman (KY)

(72) Inventors: Eric S. Kozarksy, Ballston Spa, NY (US); Hong Yu, Rexford, NY (US); Songkram Srivathanakul, Halfmoon, NY (US); Jiehui Shu, Clifton Park, NY (US); Jinping Liu, Ballston Lake, NY (US); Bryan Rice, Hillsboro, OR (US)

(21) Appl. No.: 16/151,836

(22) Filed: Oct. 4, 2018

(51) Int. Cl. H01L 21/768; H01L 21/311; H01L 21/02; H01L 21/8238

(52) U.S. Cl. CPC H01L 21/76837; H01L 21/31144; H01L 29/7843; H01L 21/0217; H01L 21/8238; H01L 21/0228

(57) ABSTRACT

One illustrative method disclosed herein includes, among other things, forming a plurality of gate structures above a semiconductor substrate, wherein a plurality of cavities are defined between adjacent gate structures, and performing a first atomic layer deposition process to form a first stressed dielectric layer in the plurality of cavities and define a first seam in each cavity of the plurality of cavities, each first seam having a height greater than a height of the adjacent gate structures.

### BACKGROUND

### 1. Field of the Disclosure

The present disclosure generally relates to the fabrication of integrated circuits, and, more particularly, to various methods of forming stress liners using atomic layer deposition to form gapfill seams.

### 2. Description of the Related Art

In modern integrated circuits, such as microprocessors, storage devices and the like, a very large number of circuit elements are provided and operated on a restricted chip area. FETs come in a variety of different configurations, e.g., planar devices, FinFET devices, nanowire devices, etc. To improve the operating speed of FETs, and to increase the density of FETs on an integrated circuit device, device designers have greatly reduced the physical size of FETs over the years, particularly the channel length of transistor devices. As a result of the reduced dimensions of the transistor devices, the operating speed of the circuit components has been increased with every new device generation, and the “packing density,” i.e., the number of transistor devices per unit area, in such products has also increased during that time.

The operating speed of FETs is also affected by the dielectric materials employed to separate the various elements of the FET. A material layer having a specified intrinsic stress may be formed above the FETs so as to thereby enhance the performance thereof. For example, compressively strained materials have been found to increase hole-mobility in P-type devices, and tensile strained materials have been found to increase electron mobility in N-type devices.

Due to the aggressive scaling employed in advanced devices, it is difficult to form strained materials between adjacent gate structures without forming voids. When contacts are subsequently formed to contact the source/drain regions of the device between the gate structures, material from the contacts may extend through the voids and cause short circuits to form between adjacent devices.

### SUMMARY

The present disclosure is directed to various methods of forming stress liners using atomic layer deposition to form gapfill seams that may avoid, or at least reduce, the effects of one or more of the problems identified above. The following presents a simplified summary of the disclosure to provide a basic understanding of some aspects of the embodiments. This summary is not an exhaustive overview of the embodiments. It is not intended to identify key or critical elements of the embodiments or to delineate the scope of the embodiments. Its sole purpose is to present some concepts in a simplified form as a prelude to the more detailed description that is discussed later.

One illustrative method disclosed includes, among other things, forming a plurality of gate structures above a semiconductor substrate, wherein a plurality of cavities are defined between adjacent gate structures, and performing a first atomic layer deposition process to form a first stressed dielectric layer in the plurality of cavities and define a first seam in each cavity of the plurality of cavities, each first seam having a height greater than a height of the adjacent gate structures.

Another illustrative method disclosed includes, among other things, forming a plurality of gate structures above a semiconductor substrate, wherein a plurality of cavities are defined between adjacent gate structures, performing a first atomic layer deposition process to form a first stressed dielectric layer in a first subset of the plurality of cavities and define a first seam in each cavity of the first subset, each first seam having a first height greater than a height of the adjacent gate structures, and performing a second atomic layer deposition process to form a second stressed dielectric layer in a second subset of the plurality of cavities and define a second seam in each cavity of the second subset, each second seam having a second height greater than the height of the adjacent gate structures, wherein the first stressed dielectric layer comprises a first stress, and the second stressed dielectric layer comprises a second stress different than the first stress.

### BRIEF DESCRIPTION OF THE DRAWINGS

The disclosure may be understood by reference to the following description taken in conjunction with the accompanying drawings, in which like reference numerals identify like elements, and in which:

FIGS. 1-8 depict various novel methods disclosed herein of forming stress liners using atomic layer deposition to form gapfill seams.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the embodiments to the particular forms disclosed, but on the contrary, the intention is to cover all modifications, equivalents, and alternatives falling within the spirit and scope of the embodiments as defined by the appended claims.

### DETAILED DESCRIPTION

Various illustrative embodiments of the embodiments are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming stress liners using atomic layer deposition to form gapfill seams. The methods and devices disclosed herein may be employed in manufacturing products using a variety of technologies, e.g., NMOS, PMOS, CMOS, etc., and they may be employed in manufacturing a variety of different devices, e.g., memory products, logic products, ASICs, etc. As will be appreciated by those skilled in the art after a complete reading of the present application, the embodiments disclosed herein may be employed in forming integrated circuit products using transistor devices in a variety of different configurations, e.g., planar devices, FinFET devices, nanowire devices, etc. The gate structures for such devices may be formed using either “gate first” or “replacement gate” manufacturing techniques. Thus, the presently disclosed embodiments should not be considered to be limited to any particular form of transistors or the manner in which the gate structures of the transistor devices are formed. Of course, the embodiments disclosed herein should not be considered to be limited to the illustrative examples depicted and described herein. With reference to the attached figures, various illustrative embodiments of the methods and devices disclosed herein will now be described in more detail. The various layers of material described below may be formed by any of a variety of different known techniques, e.g., a chemical vapor deposition (CVD) process, an atomic layer deposition (ALD) process, a thermal growth process, spin-coating techniques, etc. Moreover, as used herein and in the attached claims, the word “adjacent” is to be given a broad interpretation and should be interpreted to cover situations where one feature actually contacts another feature or is in close proximity to that other feature.

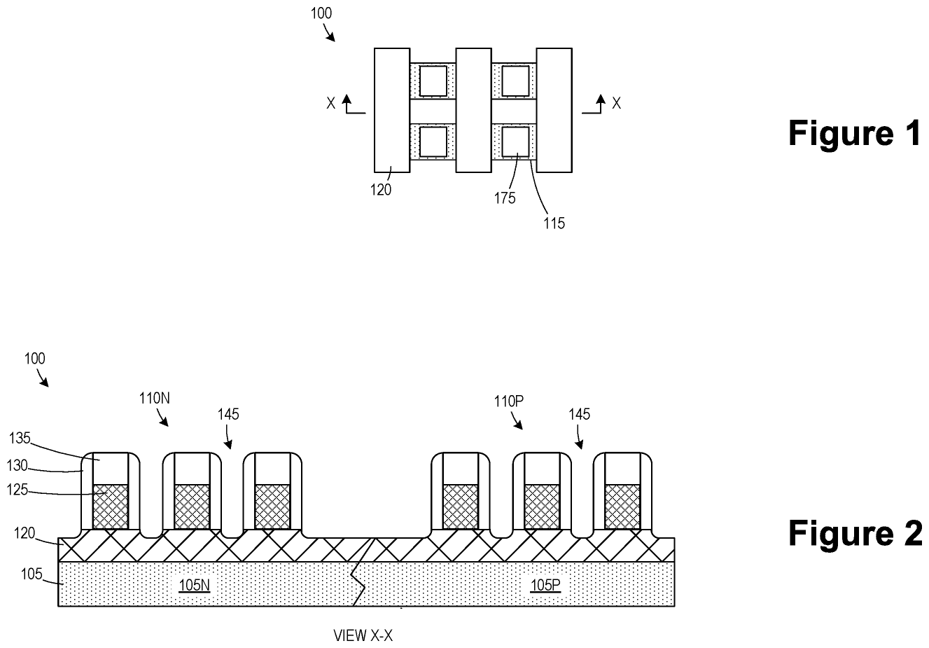

FIGS. 1-8 depict various novel methods of forming stress liners using atomic layer deposition to form gapfill seams on an integrated circuit (IC) product 100 defined in a semiconductor substrate 105. FIG. 1 represents a simplistic plan view showing where the cross-sectional views are taken in the drawings. The plan view depicts active regions, gate structures, and source/drain contacts that will eventually be formed above the semiconductor substrate 105. As indicated in FIG. 1, the view X-X is a cross-sectional view taken through the device in a direction corresponding to a gate length direction of the device in a location outside the active regions. It should be noted that not all aspects of the processing shown in the cross-sectional views will be depicted in the plan view so as to not overly complicate the drawings. For example, the plan view shows a single set of transistor devices, while the cross-sectional views illustrate multiple sets of transistors in different regions.

In the illustrated embodiment, a plurality of N-type transistor devices 110N are formed in a first region 105N of the substrate 105, and a plurality of P-type transistor devices 110P are formed in a second region 105P of the substrate 105. Additionally, various doped regions, e.g., halo implant regions, well regions, source/drain regions, and the like, may be formed, but are not depicted in the attached drawings. The substrate 105 may have a variety of configurations, such as a silicon-on-insulator (SOI) configuration that includes a bulk silicon layer, a buried insulation layer, and an active semiconductor layer (not separately shown), wherein semiconductor devices are formed in and above the active semiconductor layer. In some embodiments, the substrate 105 may have a bulk configuration. The substrate 105 may be formed of silicon or silicon germanium or it may be made of materials other than silicon, such as germanium. Thus, the terms “substrate” or “semiconductor substrate” should be understood to cover all semiconducting materials and all forms of such materials. The substrate 105 may have different layers.

A plurality of active regions 115 were defined in the substrate 105. The active regions are separated by an isolation structure 120 (e.g., shallow trench isolation (STI) structure). In embodiments employing an SOI substrate 105, the active regions 115 may be fully depleted SOI (FDSOI) regions. A plurality of gate structures 125 were positioned above the active regions 115. Source/drain regions (not shown) of the product 100 were formed in the active regions adjacent the gate structures 125 (e.g., by implantation and/or epitaxial growth). Sidewall spacers 130 are positioned on sidewalls of the gate structures 125 and dielectric cap layers 135 are positioned above the gate structures 125. The sidewall spacers 130 and the cap layers 135 may include a variety of different materials, such as silicon nitride, SiNC, SiN, SiCO, SiNOC, etc. In one illustrative embodiment, the sidewall spacers 130 and the cap layers 135 may be made of the same material. Additional regions (not shown) may be provided where the pitch of the gate structures may vary (e.g., increased pitch regions).

In some embodiments, the gate structures 125 may be manufactured using a gate first or replacement gate manufacturing technique. In general, the gate structures 125 include a gate insulation layer (e.g., silicon dioxide or a high-k dielectric, such as hafnium dioxide) and a conductive gate electrode (e.g., which may include multiple layers, such as a barrier layer, a work function material layer, a conductive fill layer, etc.) (not separately shown). Epitaxially-grown (epi) semiconductor material or silicon alloys may be formed in the source/drain regions by recessing the source/drain regions and filling the recesses with epi (e.g., silicon germanium in the P-type region 110P, silicon phosphorous or silicon carbon in the N-type region 110N). Implantation processes may also be used to introduce dopants into the source/drain regions. During the formation of the various elements of the product 100, erosion of the isolation structure 120 may occur between the gate structures 125, as illustrated in FIG. 2. This erosion increases the aspect ratio of the gaps between the gate structures 125 as compared to the aspect ratio over the active regions 115.

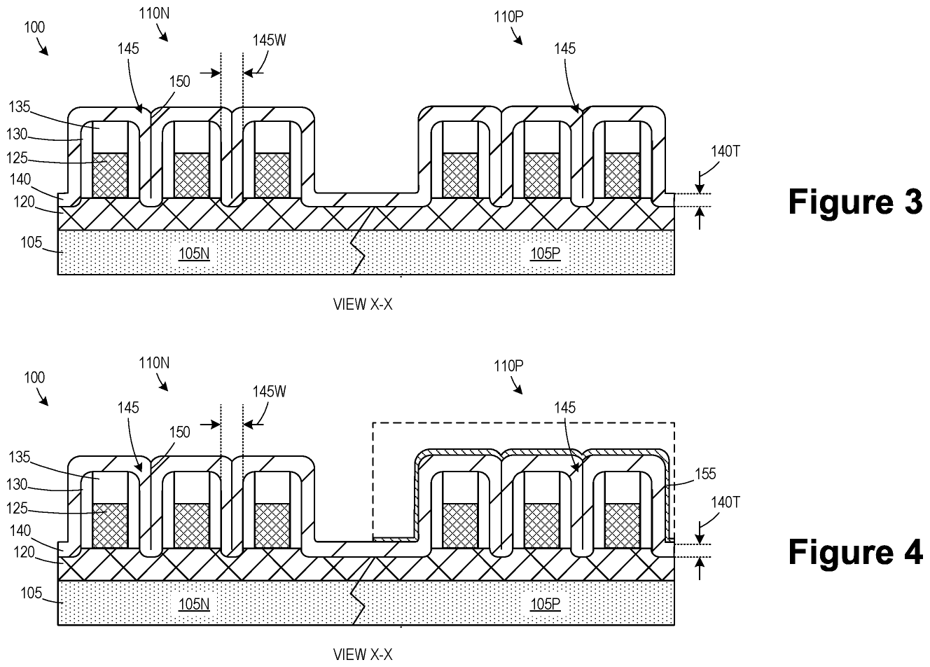

FIG. 3 illustrates the product 100 after an atomic layer deposition (ALD) process was performed to form a first stressed dielectric layer 140 (e.g., silicon nitride) above the transistors 110N, 110P and in cavities 145 between the gate structures 125 and their associated sidewall spacers 130. For example, an Applied Olympia™ process tool offered commercially by Applied Materials, Inc. of Santa Clara, Calif. may be employed to form the first stressed dielectric layer 140. The first stressed dielectric layer 140 is formed using a rotating susceptor. The rotation speed of the susceptor and the precursor materials may be varied to affect the intrinsic strain, allowing compressive or tensile stressed material to be formed. The ALD process is a conformal process where very thin layers of material (e.g., only a few atoms thick) are formed in multiple passes. The thickness 140T of the first stressed dielectric layer 140 is selected to be greater than one half the gapfill width 145W of the cavities 145, such that the conformal portions of the first stressed dielectric layer 140 disposed on vertical surfaces of the sidewall spacers 130 merge, defining seams 150. Generally, the seams 150 have a height greater than a height of the gate structures 125. In some embodiments, the seams 150 have a height greater than a combined height of the gate structures 125 and the cap layers 135.

FIG. 4 illustrates the product 100 after several processes were performed. A deposition process was performed to form a patterned mask layer 155 above the first stressed dielectric layer 140. In some embodiments, the mask layer 155 may be a hard mask layer, and a patterning process may be performed (e.g., using a photolithography process and stack) to selectively remove the mask layer 155 from above one of the regions 105N, 105P (e.g., the region 105N in the illustrated example) to expose the underlying first stressed dielectric layer 140. In some embodiments, the mask layer 155 may be a patterned photoresist layer, and the mask layer 155 would have a block shape (shown in dashed lines) rather than the conformal shape illustrated in FIG. 4.

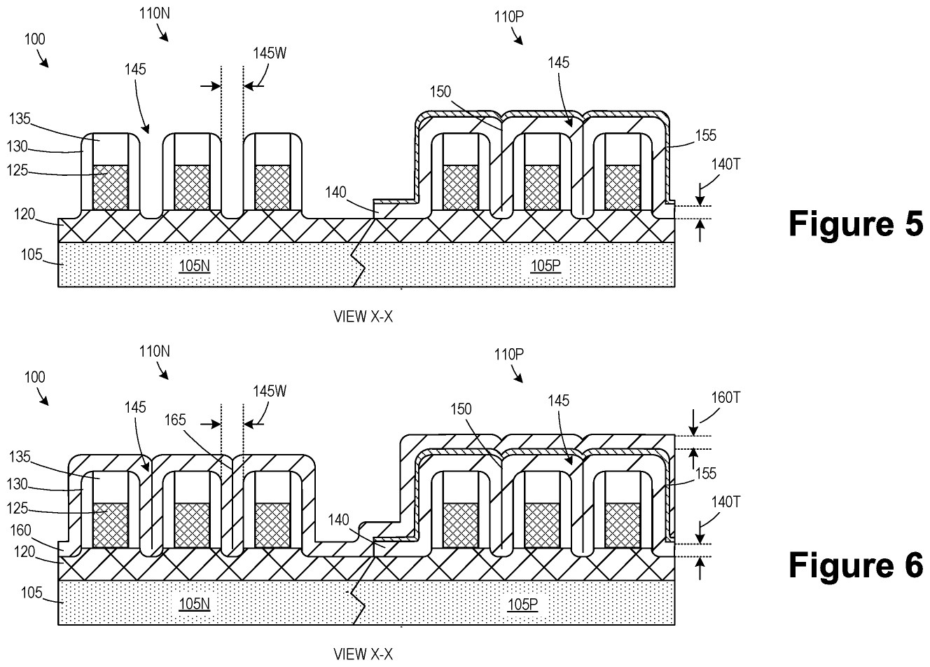

FIG. 5 illustrates the product after an etch process was performed to remove the first stressed dielectric layer 140 from above the region 105N. The removal of the first stressed dielectric layer 140 reopens the cavities 145 between the gate structures 125 and associated sidewall spacers 130 in the region 105N. An optional etch stop layer (not shown) may be formed in the cavities 145 prior to forming the first stressed dielectric layer 140 to protect the underlying transistors 110N during the subsequent removal of the first stressed dielectric layer 140 from above the region 105N. In some embodiments, the mask layer 155 may be removed after removing the first stressed dielectric layer 140.

FIG. 6 illustrates the product 100 after another ALD process was performed to form a second stressed dielectric layer 160 (e.g., silicon nitride) above the transistors 110N, 110P in both regions 105N, 105P and in the cavities 145 in the region 105N. The second stressed dielectric layer 160 may be formed using a similar process as the first stressed dielectric layer 140, with differing deposition parameters to provide a different intrinsic stress. For example, the first stressed dielectric layer 140 may be formed having a tensile stress to increase electron mobility in the transistors 110N, and the second stressed dielectric layer 160 may be formed having a compressive stress to increase hole mobility in the transistors 110P. In some embodiments, the first and second stressed dielectric layers 140, 160 may have the same stress type, but different stress magnitudes.

Again, a thickness 160T of the second stressed dielectric layer 160 is selected to be greater than one half the gapfill width 145W of the cavities 145, such that the conformal portions of the second stressed dielectric layer 160 disposed on vertical surfaces of the sidewall spacers 130 merge, defining seams 165. Generally, the seams 165 have a height greater than a height of the gate structures 125. In some embodiments, the seams 160 have a height greater than a combined height of the gate structures 125 and the cap layers 135.

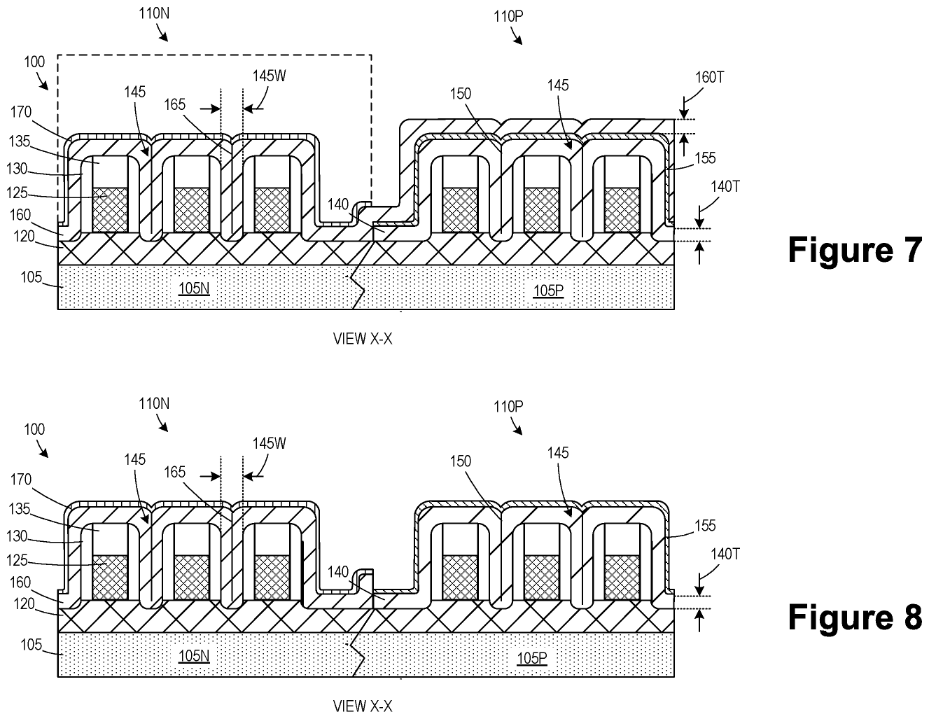

FIG. 7 illustrates the product 100 after several processes were performed. A deposition process was performed to form a mask layer 170 above the second stressed dielectric layer 160. Again, the mask layer 170 may be a hard mask layer as illustrated or a photoresist layer (shown in dashed lines)

FIG. 8 illustrates the product after an etch process was performed to remove the second stressed dielectric layer 160 above the region 105P. The mask layer 155 may be employed as an etch stop layer. In some embodiments, the mask layers 155, 170 may be removed prior to subsequent processing.

In some embodiments, the second stressed dielectric layer 160 may be left in place over the first stressed dielectric layer 140 without deleteriously affecting the strain induced by the first stressed dielectric layer 140 due to the increased distance from the transistors 110N.

Further processing may be completed to complete fabrication of the product 100. Source drain contacts 175 (shown in FIG. 1) may be formed in a dielectric layer (not shown) formed above the transistors 110N, 110P to contact source/drain regions defined in the active regions 115. Although the seams 150, 165 represent discontinuities in the stressed dielectric layers 140, 160, respectively, they are sufficiently tight due to the nature of ALD deposition processes such that conductive material of the source/drain contacts does not pass through the seams 150, 165 to cause short circuits.

The particular embodiments disclosed above are illustrative only, as the embodiments may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the embodiments. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1. A method, comprising:
forming a plurality of gate structures above a semiconductor substrate, wherein a plurality of cavities are defined between adjacent gate structures; and
performing a first atomic layer deposition process to form a first stressed dielectric layer in the plurality of cavities and define a first seam where a first portion of the first stressed dielectric layer formed adjacent a first one of the plurality of gate structures interfaces with a second portion of the first dielectric layer formed adjacent a second one of the plurality of gate structures in each cavity of the plurality of cavities, each first seam having a height greater than a height of the adjacent gate structures.

2. The method of claim 1, wherein a cap layer is positioned on a top surface of each of the plurality of gate structures, and each first seam has a height greater than a height of the cap layer formed on the adjacent gate structures.

3. The method of claim 1, further comprising:
selectively removing a first portion of the first stressed dielectric layer positioned in a first subset of the plurality of cavities, wherein a second portion of the first stressed dielectric layer remains in a second subset of the cavities; and
performing a second atomic layer deposition process to form a second stressed dielectric layer in the first subset of the plurality of cavities and define a second seam in each of the first subset of cavities where a first portion of the second stressed dielectric layer formed adjacent a third one of the plurality of gate structures interfaces with a second portion of the second dielectric layer formed adjacent a fourth one of the plurality of gate structures, each second seam having a height greater than a height of the adjacent gate structures.

4. The method of claim 3, wherein selectively removing the first portion of the first stressed dielectric layer comprises:
forming a first mask layer above the first stressed dielectric layer;
patterning the first mask layer to expose the first portion of the first stressed dielectric layer and cover the second portion of the first stressed dielectric layer; and
performing an etch process in the presence of the first mask layer to selectively remove the first portion of the first stressed dielectric layer.

5. The method of claim 3, wherein performing the second atomic layer deposition process to form the second stressed dielectric layer comprises forming a first portion of the second stressed dielectric layer in the first subset of the cavities and a second portion of the second stressed dielectric layer above the first stressed dielectric layer positioned in the second subset of the cavities.

6. The method of claim 5, further comprising selectively removing the second portion of the second stressed dielectric layer.

7. The method of claim 6, further comprising:
forming a second mask layer above the second stressed dielectric layer;
patterning the second mask layer to expose the second portion of the second stressed dielectric layer and cover the first portion of the second stressed dielectric layer; and
performing an etch process in the presence of the second mask layer to selectively remove the second portion of the second stressed dielectric layer.

8. The method of claim 3, wherein each of the cavities is separated by a first width, and a thickness of each of the first and second stressed dielectric layers is greater than half of the first width.

9. The method of claim 3, wherein the first stressed dielectric layer comprises a tensile stressed dielectric layer, and the second stressed dielectric layer comprises a compressive stressed dielectric layer.

10. The method of claim 3, wherein the first and second stressed dielectric layers have a same type of stress but different stress magnitudes.

11. The method of claim 3, wherein the first and second stressed dielectric layers comprise silicon and nitrogen.

12. The method of claim 1, wherein the first stressed dielectric layer comprises a compressive stressed dielectric layer.

13. The method of claim 1, wherein the first stressed dielectric layer comprises a tensile stressed dielectric layer.

14. A method, comprising:
forming a plurality of gate structures above a semiconductor substrate, wherein a plurality of cavities are defined between adjacent gate structures;
performing a first atomic layer deposition process to form a first stressed dielectric layer in a first subset of the plurality of cavities and define a first seam in each cavity of the first subset where a first portion of the first stressed dielectric layer formed adjacent a first one of the plurality of gate structures interfaces with a second portion of the first dielectric layer formed adjacent a second one of the plurality of gate structures, each first seam having a first height greater than a height of the adjacent gate structures; and
performing a second atomic layer deposition process to form a second stressed dielectric layer in a second subset of the plurality of cavities and define a second seam in each cavity of the second subset where a first portion of the first stressed dielectric layer formed adjacent a third one of the plurality of gate structures interfaces with a second portion of the first dielectric layer formed adjacent a fourth one of the plurality of gate structures, each second seam having a second height greater than the height of the adjacent gate structures, wherein the first stressed dielectric layer comprises a first stress, and the second stressed dielectric layer comprises a second stress different than the first stress.

15. The method of claim 14, wherein the first stress comprises a compressive stress, and the second stress comprises a tensile stress.

16. The method of claim 14, wherein performing the first atomic layer deposition process comprises forming the first stressed dielectric layer in the first subset and the second subset of the plurality of cavities, and the method further comprises:
selectively removing a first portion of the first stressed dielectric layer positioned in the second subset of the plurality of cavities, wherein a second portion of the first stressed dielectric layer remains in the first subset of the cavities; and
performing the second atomic layer deposition after selectively removing the first portion of the first stressed dielectric layer.

17. The method of claim 16, further comprising:
forming a first mask layer above the first stressed dielectric layer;
patterning the first mask layer to expose the first portion of the first stressed dielectric layer and cover the second portion of the first stressed dielectric layer; and
performing an etch process in the presence of the first mask layer to selectively remove the first portion of the first stressed dielectric layer.

18. The method of claim 17, further comprising:
forming a second mask layer above the second stressed dielectric layer;
performing the second atomic layer deposition process to form a first portion of the second stressed dielectric layer in the second subset of the cavities and a second portion of the second stressed dielectric layer above the second mask layer;
patterning the second mask layer to cover the first portion of the second stressed dielectric layer and expose the second portion of the second stressed dielectric layer; and
performing an etch process in the presence of the second mask layer to selectively remove the first portion of the second stressed dielectric layer.

19. The method of claim 14, wherein each of the cavities is separated by a first width, and a thickness of each of the first and second stressed dielectric layers is greater than half of the first width.

20. The method of claim 14, wherein the first and second stressed dielectric layers have a same type of stress but different stress magnitudes.
